(19) United States
(12) Patent Application Publication
(10) Pub. No.: US 2015/0204947 A1
(43) Pub. Date: Jul. 23, 2015

(54) DIAGNOSTIC SYSTEM AND METHOD FOR POWERED SURGICAL DEVICE

(71) Applicant: Arthrex, Inc., Naples, FL (US)

(72) Inventors: Ken Adams, Naples, FL (US); Robert Farmer, Naples, FL (US); Jerry Vitale, West Chester, PA (US)

(21) Appl. No.: 14/602,641

(22) Filed: Jan. 22, 2015

Related U.S. Application Data
(60) Provisional application No. 61/930,125, filed on Jan. 22, 2014.

(51) Int. Cl. G01R 31/34; G01R 35/00; H02K 11/00

(52) U.S. Cl. CPC G01R 31/34; H02K 11/001; G01R 35/00; G01R 33/07

(57) ABSTRACT

A method according to an exemplary aspect of this disclosure includes, among other things, electrically diagnosing a failure of a brushless DC motor of a surgical device.

### RELATED APPLICATIONS

This application claims the benefit of U.S. Provisional Application No. 61/930,125, filed Jan. 22, 2014, the entirety of which is herein incorporated by reference.

### BACKGROUND

Battery and electric powered surgical devices are commonly used in performing orthopedic surgical procedures in arthroscopic, endoscopic, large bone and small bone orthopedics. Typically, these surgical devices include a tool mounted at a distal end. Example tools include rotary shavers, drills, and cutting accessories such as sagittal and reciprocating saws. The surgical devices may also include a motor, such as a brushless DC (BLDC) motor, including a permanent magnet and a plurality of stators. The motor may also include Hall effect sensors for monitoring a position of the permanent magnet during operation of the motor.

### SUMMARY

A method according to an exemplary aspect of this disclosure includes, among other things, electrically diagnosing a failure of a brushless DC motor of a surgical device.

In a further non-limiting embodiment of the foregoing method, the method includes determining whether there has been a failure of a Hall effect sensor of the surgical device.

In a further non-limiting embodiment of the foregoing method, the surgical device includes a plurality of Hall effect sensors. Further, the method includes determining which of the Hall effect sensors of the surgical device have failed.

In a further non-limiting embodiment of the foregoing method, the method includes illuminating a light associated with the failed Hall effect sensor.

In a further non-limiting embodiment of the foregoing method, the light is illuminated a first color to indicate that the Hall effect sensor has failed, and the light is illuminated a second color to indicate that the Hall effect sensor is operating normally.

In a further non-limiting embodiment of the foregoing method, the light is mounted to one of (1) the surgical device, and (2) a unit electrically coupled to the surgical device.

In a further non-limiting embodiment of the foregoing method, the method further includes determining whether the brushless DC motor is exceeding a no-load torque.

In a further non-limiting embodiment of the foregoing method, the method further includes illuminating a light to indicate that the brushless DC motor is exceeding a no-load torque.

In a further non-limiting embodiment of the foregoing method, the method further includes determining whether the brushless DC motor is exceeding a threshold current level within a time window.

In a further non-limiting embodiment of the foregoing method, the method further includes recording and storing data indicative of the current drawn by the brushless DC motor over time.

In a further non-limiting embodiment of the foregoing method, the method further includes determining whether preventative maintenance of the brushless DC motor is required.

In a further non-limiting embodiment of the foregoing method, the method further includes selecting an appropriate motor monitoring profile based on a tool type.

A surgical device according to an exemplary aspect of the present disclosure includes, among other things, a brushless DC motor and a battery pack including circuitry configured to diagnose a failure of the brushless DC motor.

In a further non-limiting embodiment of the foregoing surgical device, the battery pack includes a plurality of batteries to power the brushless DC motor.

In a further non-limiting embodiment of the foregoing surgical device, the brushless DC motor includes a plurality of Hall effect sensors, and the battery pack includes a plurality of lights corresponding to a respective one of the Hall effect sensors.

In a further non-limiting embodiment of the foregoing surgical device, the circuitry is configured to determine whether any of the plurality of Hall effect sensors have failed.

In a further non-limiting embodiment of the foregoing surgical device, the circuitry is further configured to illuminate a light on the battery pack corresponding to a failed Hall effect sensor.

A system for diagnosing a motor of a surgical device according to an exemplary aspect of the present disclosure includes, among other things, a surgical device including a brushless DC motor, and control unit electrically coupled to the surgical device. The control unit is configured to diagnose a failure of the brushless DC motor.

In a further non-limiting embodiment of the foregoing system, the brushless DC motor includes a plurality of Hall effect sensors, and wherein control unit is configured to determine whether any of the plurality of Hall effect sensors have failed.

In a further non-limiting embodiment of the foregoing system, the control unit is configured to determine whether the brushless DC motor is exceeding a no-load torque.

The embodiments, examples and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

### BRIEF DESCRIPTION OF THE DRAWINGS

The drawings can be briefly described as follows:

FIG. 1A illustrates an example control system for a surgical device.

FIG. 1B illustrates an example diagnostic system.

FIG. 2 is a cross-sectional view taken along line 2-2 from FIG. 1A, and illustrates a portion of an example motor.

FIG. 3 illustrates an example method, including steps to monitor motor performance and to diagnose a failed motor.

FIG. 4A illustrates another example surgical device.

FIG. 4B is an end view of the surgical device of FIG. 4A.

### DETAILED DESCRIPTION

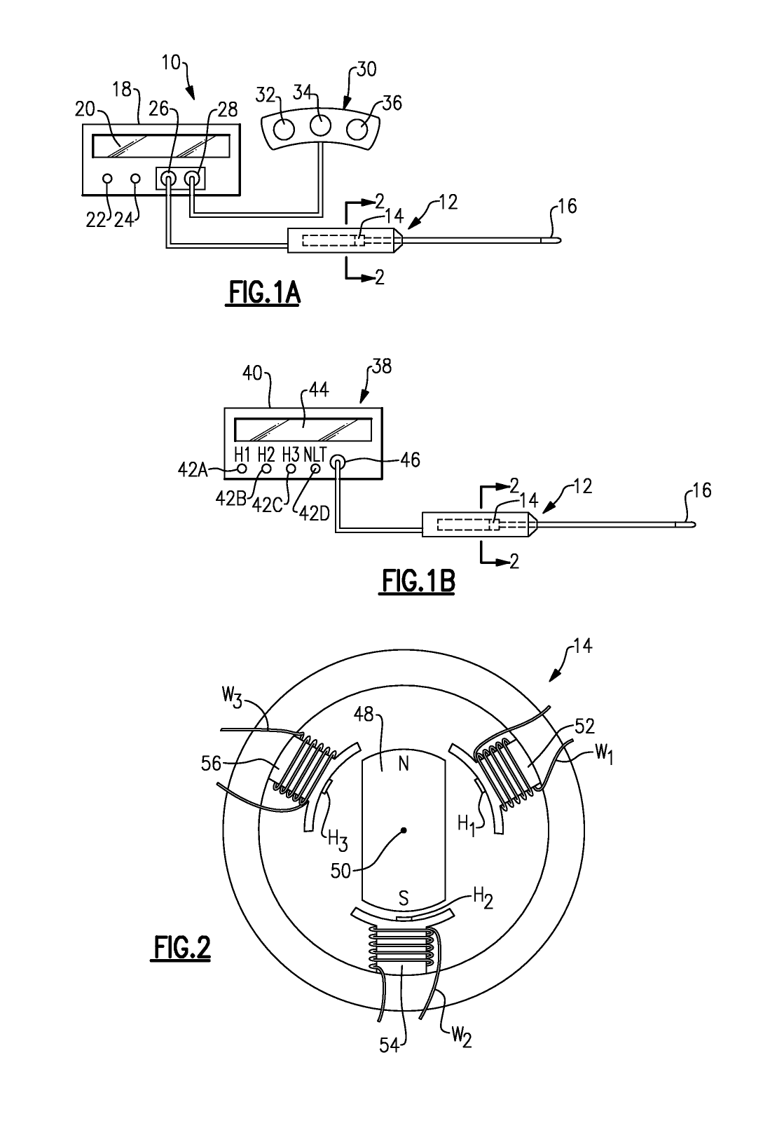

FIG. 1A schematically illustrates a control system 10 for operating a surgical device 12. In this example, the surgical device 12 includes a motor 14 (illustrated in phantom in FIG. 1A) for driving a tool 16 at a distal end of the surgical device 12. Example tools 16 include rotary shavers, drills, and sagittal and reciprocating saws. Other types of tools come within the scope of this disclosure.

The control system 10 further includes a control unit 18. In this example, the control unit 18 includes a power supply that provides electrical power to the surgical device 12. Alternatively, the surgical device 12 may include a DC battery pack that powers the motor 14. In either case, the control unit 18 may further include memory, hardware, and software configured to control operation of the surgical device 12.

The example control unit 18 includes a display 20, one or more LED indicator lights 22 (only one illustrated), one or more adjustors 24 (e.g., a dial, only one illustrated), and a plurality of electrical inlet/outlet ports 26, 28 (only two illustrated). The control system 10 may optionally include a foot switch 30 including a plurality of switches 32, 34, 36, which allow a surgeon to control the surgical device 12 at least partially with his or her feet. Additional surgical devices 12 may be connected to the control unit 18 at one time.

FIG. 1B illustrates an example diagnostic system 38. The diagnostic system 38 is used to diagnose a motor 14 of the surgical device 12, as will be explained in detail below. In the illustrated example, the diagnostic system 38 includes a diagnostic control unit 40, which, in this example, includes a plurality of LED lights 42A-42D, a display 44, and an electrical inlet/outlet port 46. Like the control unit 18, the diagnostic control unit 40 may include a power source, memory, hardware, and software configured to diagnose the motor 14. In general, the diagnostic system 38 uses the electrical connection between the motor 14 and the power source to identify if any Hall effect sensors H₁-H₃ (FIG. 2) of the motor 14 have failed. Alternatively, the diagnostic system 38 uses the electrical connection to determine if the motor 14 is using a specified current draw associated with a good motor.

The systems 10 and 38 may be separate systems, as illustrated in FIGS. 1A and 1B. On the other hand, the control system 10 could be modified to incorporate the features of the diagnostic system 38, or vice versa. That is, in one example, the control unit 18 is used to control the surgical device 12, and is also used to diagnose a failure of the motor 14.

As mentioned, the surgical device 12 may include a motor 14 configured to drive the tool 16. In one example, the motor 14 is a brushless DC (BLDC) motor. The motor 14 may further be a slotted or slotless BLDC motor. FIG. 2 schematically illustrates an example BLDC motor 14, which includes a permanent magnet 48 configured to rotate about an axis 50. Rotation of the permanent magnet 48 is translated into movement of the tool 16 using one or more known mechanical connectors.

As illustrated in FIG. 2, the permanent magnet 48 is surrounded by a plurality of stators 52, 54, 56. In this example, there are three stators 52, 54, 56 circumferentially arranged about the axis 50, and spaced approximately 120° apart from one another. While three stators are illustrated, this disclosure extends to motors 14 including different numbers of stators.

Each of the stators 52, 54, 56 supports a respective coil winding W₁-W₃, each of which is in communication with the power supply of the control unit 18. The example motor 14 further includes a plurality of Hall effect sensors H₁-H₃ mounted to a respective stator 52, 54, 56. Each of the Hall effect sensors H₁-H₃ are in communication with the control unit 18, and are used to essentially report a position of the permanent magnet 48 to the control unit 18. The control unit 18 provides an appropriate level of current to the windings W₁-W₃ depending on the signals received from the Hall effect sensors H₁-H₃.

During operation of the surgical device 12, the motor 14 may fail. As used herein, the term “failure” refers to a motor 14 that is operating below an optimal level. The term “optimal level” in this disclosure refers to a minimal threshold operational level, which may be a pre-established level corresponding to an acceptable level of performance required for surgery.

A failure of the motor 14 may be caused by a defect in one of the Hall effect sensors H₁-H₃. A failure of the motor 14 may also be indicated if the motor 14 operates at an unacceptable no-load torque level. As is known in the art, no-load torque is the torque developed at full motor speed without torque-loading the motor. A failure of one of the Hall effect sensors H₁-H₃ may be related to, or may be independent from, the motor 14 operating an unacceptable no-load torque.

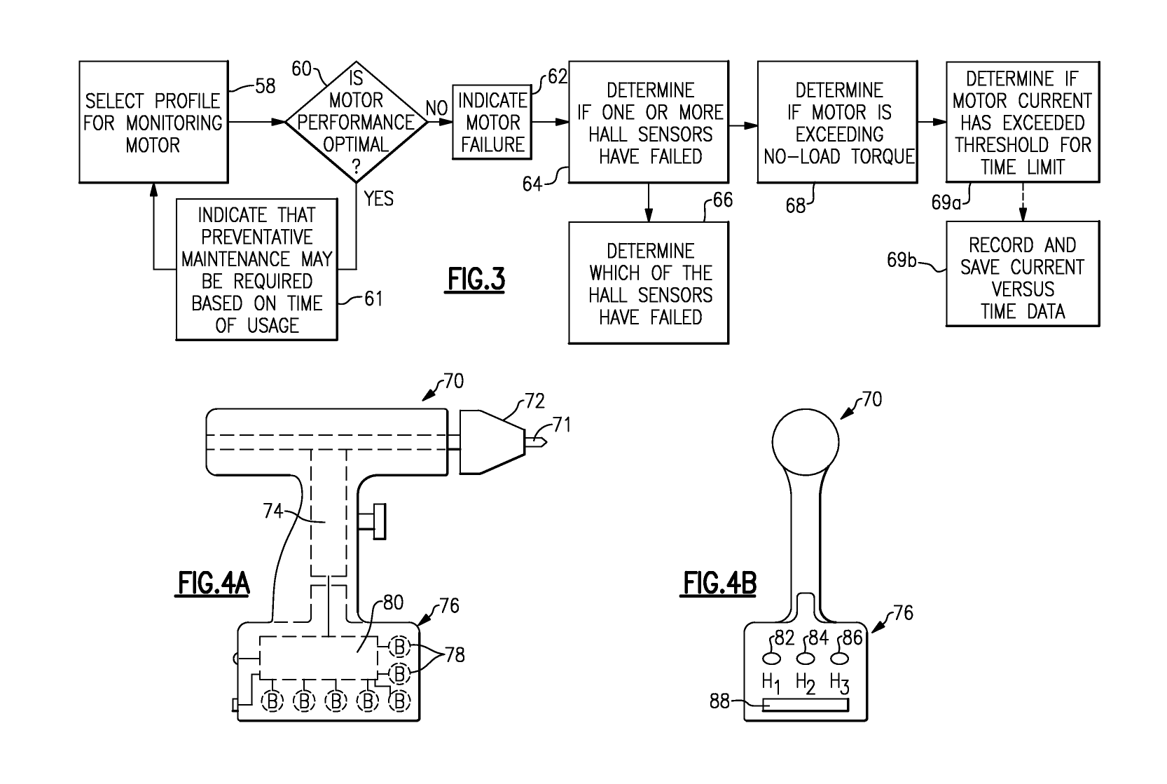

In one example method, shown in FIG. 3, the performance of the motor 14 is monitored by the control unit 18. Initially, the control unit 18 may store one or more motor monitoring profiles. These profiles may be associated with a particular tool and/or motor. For instance, the response of the motor 14 when the tool 16 is a shaver will be different than when the motor 14 is used within a drill (such as in FIG. 4). Based on the type of tool, a particular motor monitoring profile is selected at 58. The motor monitoring profile includes various thresholds, constants, and algorithms associated with the particular tool and/or motor type.

Next, using the selected profile, the control unit 18 periodically or continually determines whether the performance is optimal, at 60. Even if the performance is optimal, the control unit 18, at 61, may also trigger an alert that the motor 14 may need preventative maintenance. This alert could be triggered based on the amount of time the motor 14 has been in use during its lifetime. Additionally, it could be possible that a bearing, gear, or other mechanical component associated with the motor is beginning to fail and causing the motor to work harder. In this respect, the entire device (not just the motor) may be sent for preventative maintenance. At 62, the control unit 18 indicates a failure if the performance of the motor 14 is not optimal. In one example, alerts for motor maintenance and motor failure are communicated to the user by way of a light, such as the LED light 22. Alternatively, or in addition, a message could be communicated to a user via the display 20.

In one example, after a motor failure has been indicated, the user sends a particular surgical device 12 back to the original manufacturer. The original manufacturer may then connect the surgical device 12 to the diagnostic control unit 40. The diagnostic control unit 40 is capable of electrically diagnosing the failure of the motor 14.

In one example, that diagnosis includes determining, at 64, whether one of the Hall effect sensors H₁-H₃ has failed. If one or more of the Hall effect sensors have failed, the diagnostic control unit 40 then determines, at 66, which of the particular Hall effect sensors H₁-H₃ have failed. In one example, the diagnostic control unit 40 identifies a failure of the Hall effect sensors H₁-H₃ by monitoring the voltage generated by each sensor. In this example, there is a pre-established, acceptable lower voltage range and an acceptable upper voltage range. If, during operation, the Hall effect sensors H₁-H₃ are operating outside of the acceptable lower voltage range when in a low voltage condition, or outside the acceptable upper voltage range when in a high voltage condition, a failure is triggered. The information discovered at 66 may be communicated to a user in any manner. In one example, the lights 42A-42C illuminate either green or red, indicating normal operation or a failure respectively, for each of the Hall effect sensors H₁-H₃.

Further, at 68, the diagnostic control unit 40 may determine if there is another issue with the motor 14, such as the motor 14 operating outside an acceptable no-load torque range. Information regarding the no-load torque of the motor 14 may be communicated to the user via the LED light 42D, or in another manner.

Additionally, at 69a, the control unit 18 may also monitor—and optionally record, at 69b—the amount of current drawn by the motor 14 over time. High current draws in a short period of time could indicate that the motor 14 is exceeding a maximum operating temperature. Additionally, it may indicate that electrical components associated with the motor 14, such as a cable assembly electrically coupling the motor 14 to the control unit 18, are exceeding a maximum operating temperature. If a threshold current level (for either the motor or the cable assembly) within a time window is exceeded, this event can be communicated to the user using a light, as in the above examples, or in any other manner. At 69b, the control unit 18 can be configured to record and store the current and time data, for both the motor 14 and the cable assembly, throughout the life of the motor 14. If a failure of the motor 14 occurs, an analyst can review the current versus time log. This information may be useful in identifying the cause of the failure.

The method of FIG. 3 provides detailed information about the failure of the motor 14, which may be useful to the original manufacturer in order to make necessary repairs and assess whether future design changes may be needed. While the above discussion specifically mentions the Hall effect sensors H₁-H₃ and no-load torque, the diagnostic control unit 40 may be configured to recognize additional defects in the motor 14.

While the steps for monitoring performance of the motor 14 and diagnosing the motor 14 have been illustrated together in FIG. 3, it should be understood that these steps may be performed separately. As explained above, the control system 10 may perform the steps 58, 60, and 62, while the diagnostic system 38 may perform the steps 64, 66, and 68. Again, however, the control system 10 could perform all of the steps illustrated in FIG. 3.

While FIGS. 1A-1B illustrate the control unit 18 and the diagnostic control unit 40 as being separate units, the control unit 18 and the diagnostic control unit 40 could be incorporated into a single surgical device. One example of such a surgical device 70 is illustrated in FIG. 4A. The device 70 is configured to support a tool 71 at a distal end. As illustrated, the device 70 is a drill, and the tool 71 is a drill bit supported by a collet 72. Other tools, such as those mentioned above, come within the scope of this disclosure.

In this example, the tool 71 is driven by a motor 74 (illustrated in phantom). The surgical device 70 further includes a battery pack portion 76, which in one example is clipped into the base of the surgical device 70. The battery pack portion 76 may alternatively be integral to the surgical device 70. The battery pack portion 76 includes a plurality of batteries 78 to provide power to the motor 74. The batteries 78 may be rechargeable.

The battery pack portion 76 further includes control circuitry 80 (shown in phantom) configured to drive the motor 74 and diagnose the motor 74. That is, the control circuitry 80 is configured to perform the functions of the control unit 18 and the diagnostic control unit 40, as substantially described above.

As illustrated in FIG. 4B, which is an end view of the surgical device 70, the battery pack portion 76 may include a plurality of LED lights 82, 84, 86, and 88. In this example, the lights 82, 84, 86 illuminate to indicate the performance of the hall sensors H₁-H₃, respectively, as substantially described above (e.g., the lights 82, 84, 86 could illuminate either “red” or “green”). Similarly, a fourth light 88 may illuminate to indicate the no-load torque of the motor 74.

It should be understood that terms such as “distal” and “proximal” have been used herein for purposes of explanation, and should not be considered otherwise limiting. Terms such as “generally,” “substantially,” and “about” are not intended to be boundaryless terms, and should be interpreted consistent with the way one skilled in the art would interpret the term.

Although the different examples have the specific components shown in the illustrations, embodiments of this disclosure are not limited to those particular combinations. It is possible to use some of the components or features from one of the examples in combination with features or components from another one of the examples.

One of ordinary skill in this art would understand that the above-described embodiments are exemplary and non-limiting. That is, modifications of this disclosure would come within the scope of the claims. Accordingly, the following claims should be studied to determine their true scope and content.

What is claimed is:

1. A method, comprising:
electrically diagnosing a failure of a brushless DC motor of a surgical device.

2. The method as recited in claim 1, further comprising:
determining whether there has been a failure of a Hall effect sensor of the surgical device.

3. The method as recited in claim 2, wherein the surgical device includes a plurality of Hall effect sensors, and further comprising determining which of the Hall effect sensors of the surgical device have failed.

4. The method as recited in claim 3, including illuminating a light associated with the failed Hall effect sensor.

5. The method as recited in claim 4, wherein the light is illuminated a first color to indicate that the Hall effect sensor has failed, and wherein the light is illuminated a second color to indicate that the Hall effect sensor is operating normally.

6. The method as recited in claim 4, wherein the light is mounted to one of (1) the surgical device, and (2) a unit electrically coupled to the surgical device.

7. The method as recited in claim 1, further comprising:
determining whether the brushless DC motor is exceeding a no-load torque.

8. The method as recited in claim 7, further comprising:
illuminating a light to indicate that the brushless DC motor is exceeding a no-load torque.

9. The method as recited in claim 1, further comprising:
determining whether the brushless DC motor is exceeding a threshold current level within a time window.

10. The method as recited in claim 1, further comprising:
recording and storing data indicative of current drawn by the brushless DC motor over time.

11. The method as recited in claim 1, further comprising:
determining whether preventative maintenance of the brushless DC motor is required.

12. The method as recited in claim 1, further comprising:
selecting an appropriate motor monitoring profile based on a tool type.

13. A surgical device, comprising:
a brushless DC motor; and
a battery pack including circuitry configured to diagnose a failure of the brushless DC motor.

14. The surgical device as recited in claim 13, wherein the battery pack includes a plurality of batteries to power the brushless DC motor.

15. The surgical device as recited in claim 13, wherein the brushless DC motor includes a plurality of Hall effect sensors, and wherein the battery pack includes a plurality of lights corresponding to a respective one of the Hall effect sensors.

16. The surgical device as recited in claim 15, wherein the circuitry is configured to determine whether any of the plurality of Hall effect sensors have failed.

17. The surgical device as recited in claim 16, wherein the circuitry is further configured to illuminate a light on the battery pack corresponding to a failed Hall effect sensor.

18. A system for diagnosing a motor of a surgical device, comprising:
a surgical device including a brushless DC motor; and
a control unit electrically coupled to the surgical device, the control unit configured to diagnose a failure of the brushless DC motor.

19. The system as recited in claim 18, wherein the brushless DC motor includes a plurality of Hall effect sensors, and wherein control unit is configured to determine whether any of the plurality of Hall effect sensors have failed.

20. The system as recited in claim 18, wherein the control unit is configured to determine whether the brushless DC motor is exceeding a no-load torque.
